(19) United States
(12) Patent Application Publication
(10) Pub. No.: US 2020/0385263 A1
(43) Pub. Date: Dec. 10, 2020

(54) PACKAGE STRUCTURE OF MICRO-ELECTRO-MECHANICAL-SYSTEM (MEMS) MICROPHONE PACKAGE AND PACKAGING METHOD THEREOF

(71) Applicant: Solid State System Co., Ltd., Hsinchu (TW)

(72) Inventors: Chien-Hsing Lee, Hsinchu County (TW); Tsung-Min Hsieh, New Taipei City (TW)

(73) Assignee: Solid State System Co., Ltd., Hsinchu (TW)

(21) Appl. No.: 16/432,936

(22) Filed: Jun. 6, 2019

(51) Int. Cl. B81C 1/00; B81B 7/00; H04R 1/04; H04R 19/04; H04R 19/00; H04R 31/00

(52) U.S. Cl. CPC B81C 1/00269; B81B 7/0064; H04R 1/04; H04R 19/04; H04R 19/005; H04R 31/003; H04R 2201/003; B81B 2207/012; B81B 2207/097; B81B 2207/093; B81B 2207/115; B81C 2203/0792; B81C 2203/036; B81B 2201/0257

(57) ABSTRACT

A package structure of micro-electro-mechanical-system microphone includes a ceramic packaging substrate, embedded with a first circuit route, wherein the first circuit route includes a first metal sealing ring on a surface of the ceramic packaging substrate. An integrated circuit is disposed on the surface of the ceramic packaging substrate. A MEMS microphone die is disposed on the surface of the ceramic packaging substrate, wherein the MEMS microphone die is electrically connected to the integrated circuit. A cap structure is disposed on the first metal sealing ring of the ceramic packaging substrate, wherein the cap structure has a second metal sealing ring on a surface of the cap structure, wherein the second metal sealing ring is disposed on the first metal sealing ring, so that the cap structure covers on the ceramic packaging substrate.

### BACKGROUND

### 1. Field of the Invention

The invention is related to MEMS (Micro Electro Mechanical System) microphone package technology.

### 2. Description of Related Art

Microphone has been designed based on semiconductor fabrication technology, so as to greatly reduce the size. The MEMS microphone is a popular device used in electronic apparatus to sense acoustic signals, such as the communication voice.

After the MEMS microphones are fabricated on a wafer and cut into multiple dies, the MEMS microphone in single die is connected to an integrated circuit, such as an application-specific integrated circuit (ASIC), by packaging process.

To have a proper protection on the microphone with the ASIC, a metal cap is usually used to cover the MEMS microphone during the packaging process. Conventionally, the metal cap is disposed over a packaging substrate by a tin solder paste, so as to ground the metal cap.

Since the tin solder paste would splash at a high temperature, the splashed tin solder paste may contaminate the ASIC and/or the MEMS microphone. The MEMS microphone package may have a defect resulting in a reduced performance.

How to package the MEMS microphone to avoid the contamination from the solder paste is still an issue in the packaging process.

### SUMMARY OF THE INVENTION

The invention provides a package structure, which may not include solder paste to join the cap structure onto the packaging substrate. The contamination from solder paste may be avoided.

In an embodiment, the invention provides a package structure of MEMS microphone, which includes a ceramic packaging substrate, embedded with a first circuit route, wherein the first circuit route comprises a first metal sealing ring on a surface of the ceramic packaging substrate. An integrated circuit is disposed on the surface of the ceramic packaging substrate. A MEMS microphone die is disposed on the surface of the ceramic packaging substrate, wherein the MEMS microphone die is electrically connected to the integrated circuit. A cap structure has a second metal sealing ring on a surface of the cap structure. The second metal sealing ring is disposed on the first metal sealing ring, so that the cap structure covers on the ceramic packaging substrate.

In an embodiment, the invention provides a package structure of electro-mechanical-system (MEMS) microphone, comprising a ceramic packaging substrate, embedded with a circuit route, wherein the circuit route comprises a metal sealing ring on a surface of the ceramic packaging substrate, the circuit route also comprises a circuit pad on the surface of the ceramic packaging substrate. An integrated circuit is disposed on the surface of the ceramic packaging substrate and connected to circuit pad of the circuit route. A MEMS microphone die is disposed on the surface of the ceramic packaging substrate, wherein the MEMS microphone die is electrically connected to the integrated circuit. A metal cap structure is disposed on the first metal sealing ring.

In an embodiment, the invention provides a packaging method for MEMS microphone, which includes providing a ceramic packaging substrate, embedded with a first circuit route, wherein the first circuit route comprises a first metal sealing ring on a surface of the ceramic packaging substrate. An integrated circuit is disposed on the surface of the ceramic packaging substrate. A MEMS microphone die is disposed on the surface of the ceramic packaging substrate, wherein the MEMS microphone is electrically connected to the integrated circuit. A cap structure is provided, having a second metal sealing ring on a surface of the cap structure. A bonding process is applied to at least bond the second metal sealing ring and the first metal sealing ring, so that the cap structure covers on the ceramic packaging substrate.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1, schematically illustrating an issue of a package structure of MEMS microphone as looked into, according to an embodiment of the invention.

FIG. 2 schematically illustrating a ceramic packaging substrate and a cap structure for a package structure of MEMS microphone, according to an embodiment of the invention.

FIG. 3 schematically illustrating a cross-sectional view of a package structure of MEMS microphone, according to an embodiment of the invention.

FIG. 4 schematically illustrating a layout of the cap structure of the package structure in FIG. 3, according to an embodiment of the invention.

FIG. 5 schematically illustrating a layout of the ceramic packaging substrate of the package structure in FIG. 3, according to an embodiment of the invention.

FIG. 6 schematically illustrating a cross-sectional view of a package structure of MEMS microphone, according to an embodiment of the invention.

FIG. 7 schematically illustrating a layout of the cap structure of the package structure in FIG. 6, according to an embodiment of the invention.

FIG. 8 schematically illustrating a layout of the ceramic packaging substrate of the package structure in FIG. 6, according to an embodiment of the invention.

FIG. 9 schematically illustrating a cross-sectional view of a package structure of MEMS microphone, according to an embodiment of the invention.

FIG. 10 schematically illustrating a layout of the cap structure of the package structure in FIG. 9, according to an embodiment of the invention.

FIG. 11 schematically illustrating a layout of the ceramic packaging substrate of the package structure in FIG. 9, according to an embodiment of the invention.

FIG. 12 schematically illustrating a cross-sectional view of a package structure of MEMS microphone, according to an embodiment of the invention.

FIG. 13 schematically illustrating a cross-sectional view of a package structure of MEMS microphone, according to an embodiment of the invention.

FIG. 14 schematically illustrating a cross-sectional view of a package structure of MEMS microphone, according to an embodiment of the invention.

FIG. 15 schematically illustrating a cross-sectional view of a package structure of MEMS microphone, according to an embodiment of the invention.

FIG. 16A to FIG. 16E schematically illustrating a packaging process of MEMS microphone, according to an embodiment of the invention.

### DESCRIPTION OF THE EMBODIMENTS

The invention is directed to a structure of MEMS microphone package and a method for packaging the MEMS microphone. The solder paste may be not involved in the packaging structure. The contamination from the solder paste is effectively avoided.

Several embodiments are provided for describing the invention but the invention is not limited to the embodiments as provided. Further, a proper combination between the embodiments may also be further made.

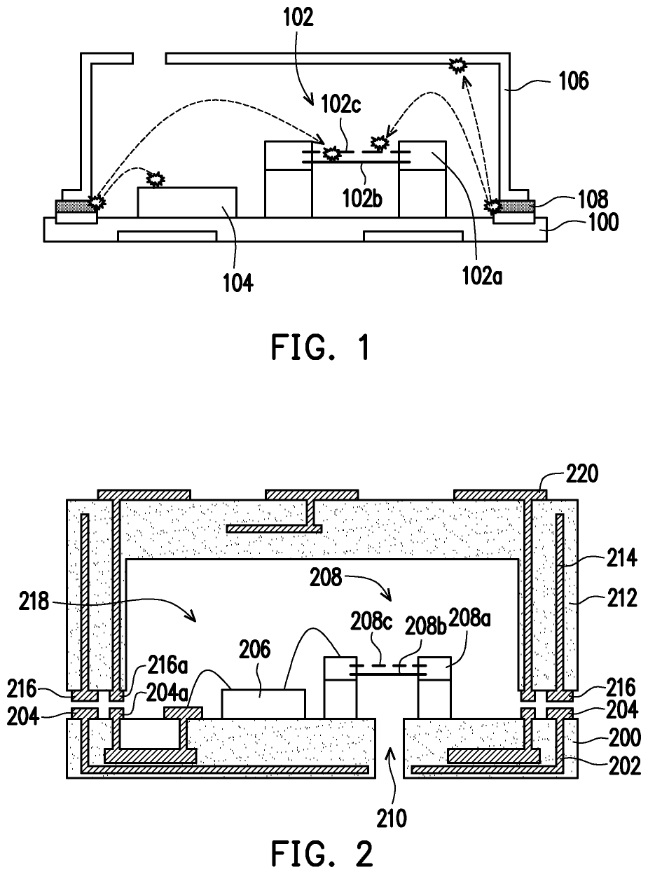

FIG. 1, schematically illustrating an issue of a package structure of MEMS microphone as looked into, according to an embodiment of the invention. Referring to FIG. 1, the invention has looked into the contamination issue from solder paste in a package structure of MEMS microphone. The package structure of MEMS microphone usually includes a package substrate 100 and a cap structure 106. A MEMS microphone die 102 and an integrated circuit 104 are packaged on the package substrate 100. The MEMS microphone die 102 basically includes supporting structure 102a, a diaphragm 102b, and a back plate 102a. The cap structure 106 is used to protect the MEMS microphone die 102 and the integrated circuit 104. The cap structure 106 covers over the MEMS microphone die 102 and the integrated circuit 104 and is firmly joined to the package substrate 100 by the solder paste 108. During the packaging stage to join the cap structure 106 and the package substrate 100, the solder paste 108 in the transient liquid state may splash over the MEMS microphone die 102 and/or the integrated circuit 104, causing contamination. This issue as looked into by the invention needs to be effectively avoided.

FIG. 2 schematically illustrating a ceramic packaging substrate and a cap structure for a package structure of MEMS microphone, according to an embodiment of the invention. Referring to FIG. 2, after looking into the contamination issue from the solder paste, the invention has provided a package structure of MEMS microphone based on the ceramic packaging substrate 200. The ceramic packaging substrate 200 is provided for packaging an integrated circuit 206 and a MEMS microphone die 208. The ceramic packaging substrate 200 has a circuit route 202 as embedded inside ceramic packaging substrate 200. The circuit route 202 includes a metal sealing ring 204 on a surface of the ceramic packaging substrate 200. The metal sealing ring 204 in an embodiment is surrounding the integrated circuit 206 and the MEMS microphone die 208. In an embodiment, the metal sealing ring 204 is closely surrounding the integrated circuit 206 and the MEMS microphone die 208, as preserved to join the cap structure 212. The circuit route 202 may also include a circuit pad 204a within the metal sealing ring 204.

The ceramic packaging substrate 200 is used to package the integrated circuit 206 and the MEMS microphone die 208 on the same surface of the ceramic packaging substrate 200 having the metal sealing ring 204 and the circuit pad 204a. The MEMS microphone die 208 in an embodiment includes a supporting structure 208a, a diaphragm 208b and a backplate 208c. In an embodiment, the ceramic packaging substrate 200 has an acoustic hole 210 in accordance with the MEMS microphone die 208, so as to sense the sound.

The cap structure 212 in an embodiment is also a ceramic cap, which may be embedded with another circuit route 214. Further, a connection pad 220 may formed on the cap structure 212 for further external connection. Likewise to the ceramic packaging substrate 200, the circuit route 214 also includes a metal sealing ring 216, disposed on a surface of the cap structure 212. The metal sealing ring 216 of the cap structure 212 is to be joined to the metal sealing ring 204 of the ceramic packaging substrate 200. The circuit route 214 further includes the circuit pad 216a in accordance with the function of the circuit route 214. In an embodiment, the ceramic packaging substrate 200 is a planar layer, so that the surface of the ceramic packaging substrate 200 to be disposed with the integrated circuit 206 and the MEMS microphone die 208 is a flat surface. However, the surface of the cap structure 212 may have a depression portion, so as to provide a space 218 to adapt the MEMS microphone die 208. The space 218 allows the diaphragm 208a of the MEMS microphone die 208 to efficiently vibrate corresponding to the air pressure caused by the acoustic signal.

As noted, a portion of the circuit route 202 and the circuit route 214 as connected to the metal sealing rings 204, 216 may provide a shielding structure, which may include a vertical wall and/or a horizontal layer. However, the shielding structure is not limited to the embodiment as provided.

The ceramic packaging substrate 200 and the cap structure 212 may be separately provided. The MEMS microphone die 208 and the integrated circuit 206 are firstly packaged onto the ceramic packaging substrate 200, then the cap structure 212 is further packaged onto the ceramic packaging substrate 200.

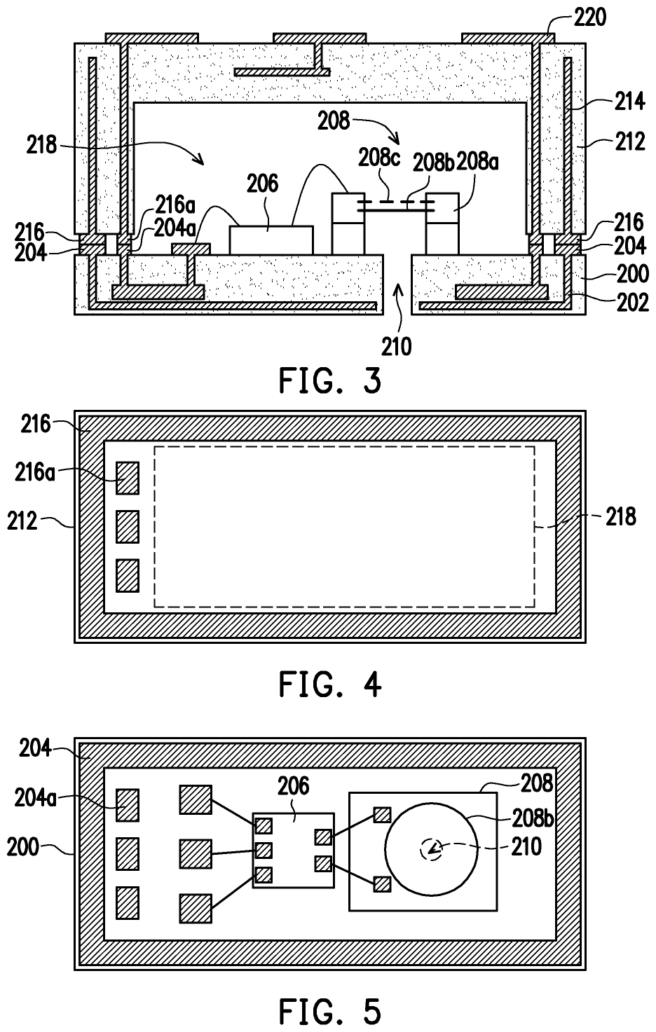

FIG. 3 schematically illustrating a cross-sectional view of a package structure of MEMS microphone, according to an embodiment of the invention. FIG. 4 schematically illustrating a layout of the cap structure of the package structure in FIG. 3, according to an embodiment of the invention. FIG. 5 schematically illustrating a layout of the ceramic packaging substrate of the package structure in FIG. 3, according to an embodiment of the invention.

Referring to FIGS. 3-5, the cap structure 212 is packaged onto the ceramic packaging substrate 200 as a package structure of MEMS microphone. The mechanism to join the cap structure 212 and the ceramic packaging substrate 200 is bonding the metal sealing ring 204 of the ceramic packaging substrate 200 with the metal sealing ring 216 of the cap structure 212, in which the circuit pad 204 of the ceramic packaging substrate 200 may also be bonded to the metal sealing ring 216 of the cap structure 212, simultaneously. The bonding process may use eutectic technology or welding technology. In an example, the eutectic technology would apply an ultrasonic vibration between the metal sealing ring 204 and the metal sealing ring 216 at the interface for a short time. Due to fast vibration, a great amount of friction induces high temperature to melt the metal material at the friction interface. After cooling, the two metal sealing rings 204, 216 are firmly joined and the two circuit pads 204a, 216a are also firmly joined.

To FIG. 4, the metal sealing ring 216 of the cap structure 212 in an embodiment is surrounding the MEMS microphone die 208 and the integrated circuit 206. The circuit pad 216a is also within the metal sealing ring 216. In an embodiment, the metal sealing ring 216 may be fully surrounding the MEMS microphone die 208 and the integrated circuit 206. To FIG. 5, the metal sealing ring 204 of the ceramic packaging substrate 200 is conformal to the metal sealing ring 216 of the cap structure 212. After joining the ceramic packaging substrate 200 and the cap structure 212, the metal sealing rings 204, 216 may seal the space 218 except the acoustic hole 210.

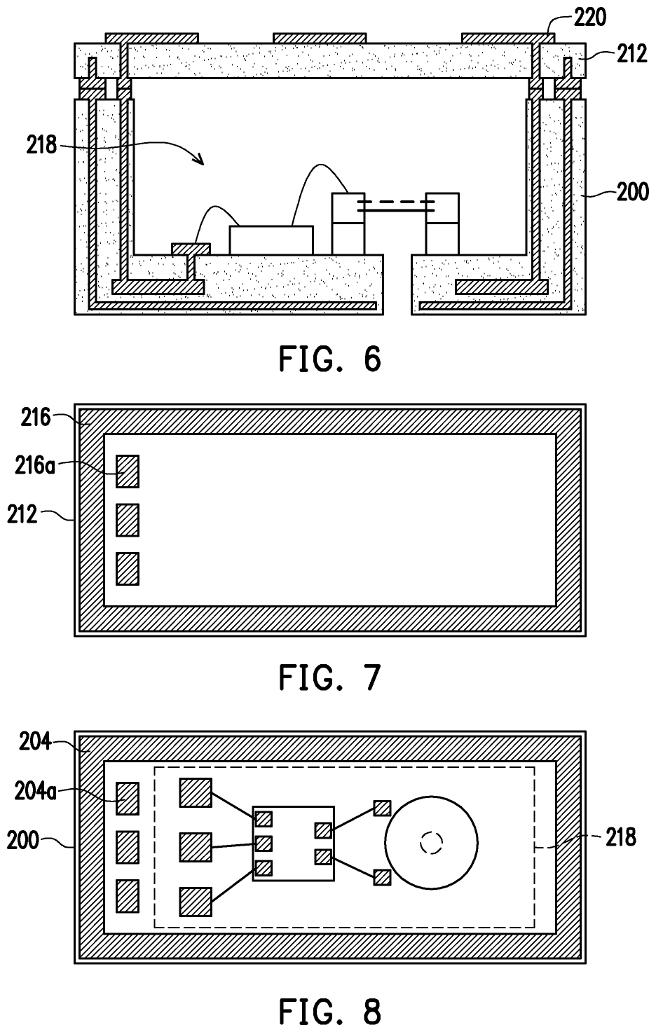

With the metal sealing rings 204, 216, the ceramic packaging substrate 200 and the cap structure 212 may be further modified. FIG. 6 schematically illustrating a cross-sectional view of a package structure of MEMS microphone, according to an embodiment of the invention. FIG. 7 schematically illustrating a layout of the cap structure of the package structure in FIG. 6, according to an embodiment of the invention. FIG. 8 schematically illustrating a layout of the ceramic packaging substrate of the package structure in FIG. 6, according to an embodiment of the invention.

Referring to FIGS. 6-8, in an embodiment, the surface of the ceramic packaging substrate 200 may have a depression portion to adapt the MEMS microphone die 208 and the integrated circuit 206. The depression portion provides the space 218, which is needed to assure the sensitivity of the MEMS microphone die. In the embodiment, the cap structure 212 may be a flat layer to simply cover on the ceramic packaging substrate 200. However, the ceramic packaging substrate 200 provides the spacer 218 at the depression portion.

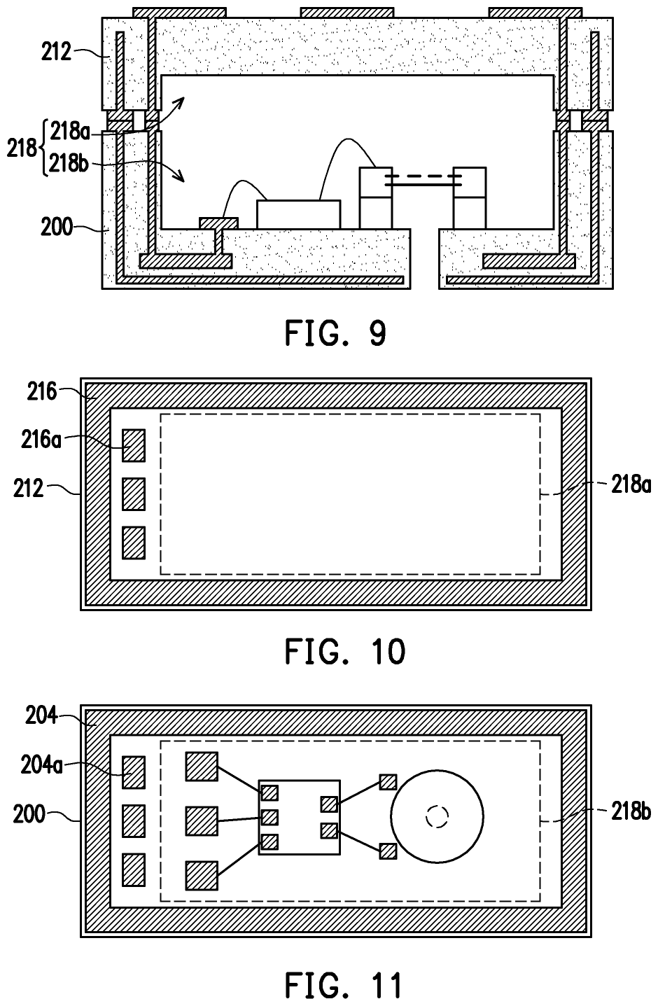

FIG. 9 schematically illustrating a cross-sectional view of a package structure of MEMS microphone, according to an embodiment of the invention. FIG. 10 schematically illustrating a layout of the cap structure of the package structure in FIG. 9, according to an embodiment of the invention. FIG. 11 schematically illustrating a layout of the ceramic packaging substrate of the package structure in FIG. 9, according to an embodiment of the invention.

Referring to FIGS. 9-11, in the further modification to FIG. 9, the cap structure 212 may also include a depression portion. In this situation, the cap structure 212 provides a space 218b and the ceramic packaging substrate 200 provides a space 218a. The space 218a of the ceramic packaging substrate 200 and the space 218b of the cap structure 212 together form the space 218. The layouts of the cap structure 212 and the ceramic packaging substrate 200 in plane view except the space 218 are same to the layouts in FIG. 7 and FIG. 8.

It can be noted that, the cap structure 212 and the ceramic packaging substrate 200, respectively, may have the depression or be a flat layer. A proper combination of the cap structure 212 and the ceramic packaging substrate 200 may be taken according to the actual design without limiting to the embodiments as provided.

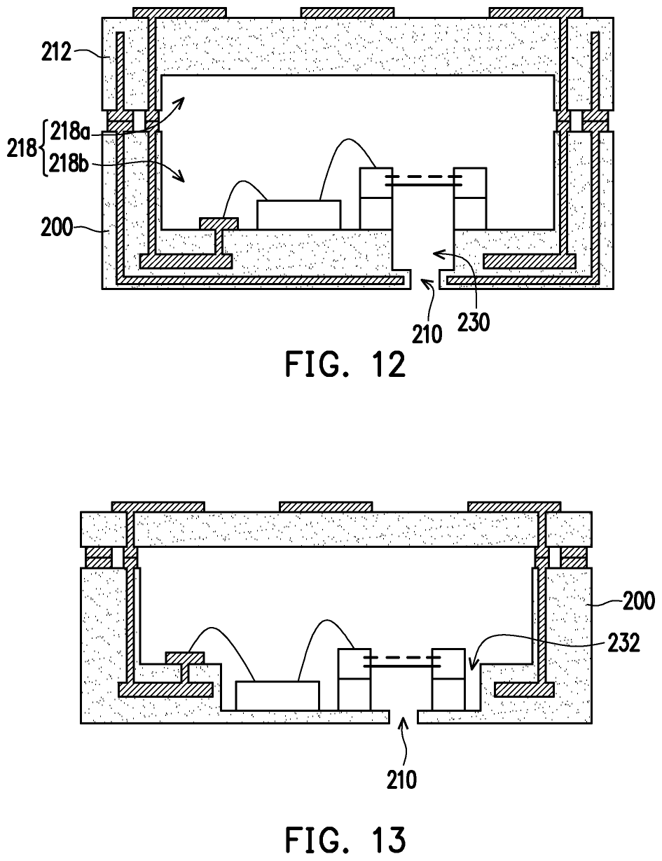

The further modifications on the cap structure 212 or the ceramic packaging substrate 200 are provided. FIG. 12 schematically illustrating a cross-sectional view of a package structure of MEMS microphone, according to an embodiment of the invention. Referring to FIG. 12, the ceramic packaging substrate 200 may be further modified to have an indent 230, which is corresponding to a chamber of the MEMS microphone die 208 for receiving the acoustic signal. The indent 230 is under the MEMS microphone die 208 produces more free space of the chamber of the MEMS microphone die 208 against the space 218, so that the diaphragm can be more easily vibrate.

FIG. 13 schematically illustrating a cross-sectional view of a package structure of MEMS microphone, according to an embodiment of the invention. Referring to FIG. 13, a further modification is that the indent 232 of the ceramic packaging substrate 200 may be further formed, so to adapt the integrated circuit 206 and the MEMS microphone die 208. The cap structure may take the cap structure 212 with flat layer in FIG. 6 or the cap structure 212 with depression in FIG. 9. In the embodiment, the cap structure takes the cap structure 212 with the flat layer in FIG. 6.

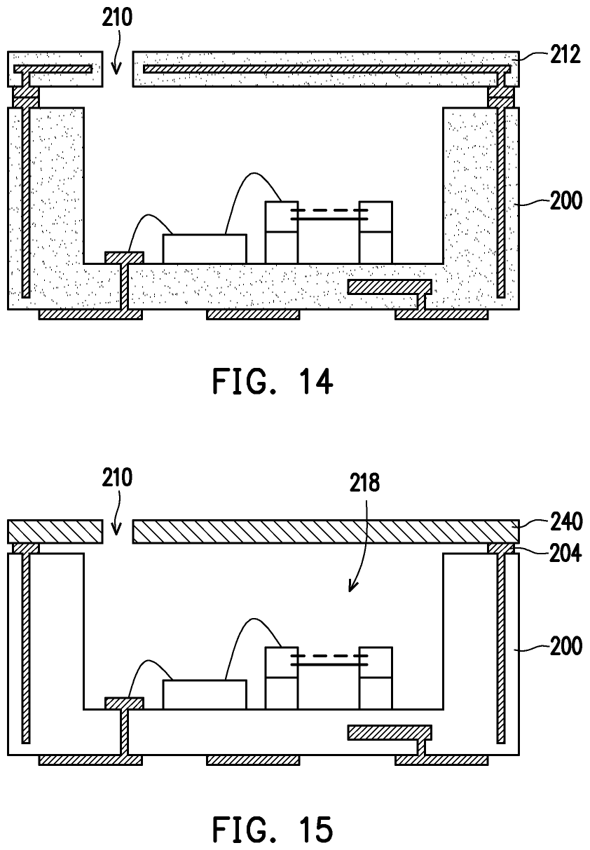

FIG. 14 schematically illustrating a cross-sectional view of a package structure of MEMS microphone, according to an embodiment of the invention. Referring to FIG. 14, depending on the operation choice of the MEMS microphone, the acoustic hole 210 may be formed in the cap structure 212 instead of the acoustic hole 210 in the ceramic packaging substrate 200 for the foregoing embodiments. As also noted, the cap structure 212 and the ceramic packaging substrate 200 may or may not respectively have the depression as described in foregoing embodiments. In the embodiment, the cap structure 212 is a flat layer as an example. The acoustic hole 210 is formed in the cap structure 212. In addition, the circuit route embedded in the cap structure 212 of ceramic material may include a portion, such as a plane portion, to serve as a shielding component. The circuit route embedded in the ceramic packaging substrate 200 with the depression may include the vertical wall to serve as a shielding component.

FIG. 15 schematically illustrating a cross-sectional view of a package structure of MEMS microphone, according to an embodiment of the invention. Referring to FIG. 15, the ceramic packaging substrate 200 may have or have not the depression as described in foregoing embodiments. In the embodiment, the ceramic packaging substrate 200 has the depression as an example for description. The cap structure 210 in foregoing embodiments may be replaced by a metal cap structure 240. The metal cap structure 240 may also have the acoustic hole 210 in an example. However, the metal cap structure 240 may be directly bonded to the metal sealing ring 204. In this embodiment, sine the ceramic packaging substrate 200 has the depression to form the space 218, the metal cap structure 240 may be a flat layer without depression. However, the metal cap structure 240 may be bent to have depression as well to provide the space 218 as needed. The invention is not limited to the embodiment. Further in the embodiment, a portion of the metal cap structure 240 is reserved to join to the metal sealing ring 204 and then may be treated as another metal sealing ring, serving the same function of the metal sealing ring 216 in foregoing embodiments. Further in an embodiment, based on the features in the foregoing embodiment, a portion of the metal cap structure 240 in contacting with the metal sealing ring 204 of the ceramic packaging substrate 200 may function as another metal sealing ring of the metal cap structure 240.

Based on the foregoing descriptions, in an embodiment of the package structure of MEMS microphone, the first circuit route further comprises: a first circuit route embedded in the ceramic packaging substrate; and a first circuit pad on the surface of the ceramic packaging substrate. The cap structure is embedded with a second circuit route, the second circuit route comprises the second metal sealing ring and further comprises: a second circuit route embedded in the cap structure; and a second circuit pad on the surface of the cap structure. The second circuit pad is also disposed on the first circuit pad.

In an embodiment of the package structure of MEMS microphone, the surface of the ceramic packaging substrate is a flat surface to accept the MEMS microphone and the integrated circuit. The surface of the cap structure has a depression portion corresponding to the MEMS microphone and the integrated circuit.

In an embodiment of the package structure of MEMS microphone, the surface of the ceramic packaging substrate has a depression portion to accept the MEMS microphone die and the integrated circuit. The surface of the cap structure is a flat surface.

In an embodiment of the package structure of MEMS microphone, the surface of the ceramic packaging substrate has a first depression portion to accept the MEMS microphone and the integrated circuit. The surface of the cap structure has a second depression portion corresponding to the MEMS microphone die and the integrated circuit.

In an embodiment of the package structure of MEMS microphone, the surface of the ceramic packaging substrate has a first depression portion to accept the MEMS microphone die and the integrated circuit and the ceramic packaging substrate further has an indent under the MEMS microphone die or under both the MEMS microphone die and the integrated circuit. The surface of the cap structure has a second depression portion corresponding to the MEMS microphone and the integrated circuit.

In an embodiment of the package structure of MEMS microphone, the surface of the ceramic packaging substrate is a flat surface or has a depression portion to accept the MEMS microphone and the integrated circuit.

In an embodiment of the package structure of M EMS microphone, the surface of the cap structure is a flat surface or has a depression portion.

In an embodiment of the package structure of MEMS microphone, one of the ceramic packaging substrate and the cap structure has an acoustic hole.

In an embodiment of the package structure of MEMS microphone, the cap structure is ceramic and comprises a shielding metal layer as embedded and connected to the second metal sealing ring.

In an embodiment of the package structure of MEMS microphone, the ceramic packaging substrate comprises a vertical metal wall as embedded and connected to the first metal sealing ring.

In an embodiment of the package structure of MEMS microphone, the cap structure is ceramic and comprises a shielding metal wall as embedded and connected to the second metal sealing ring.

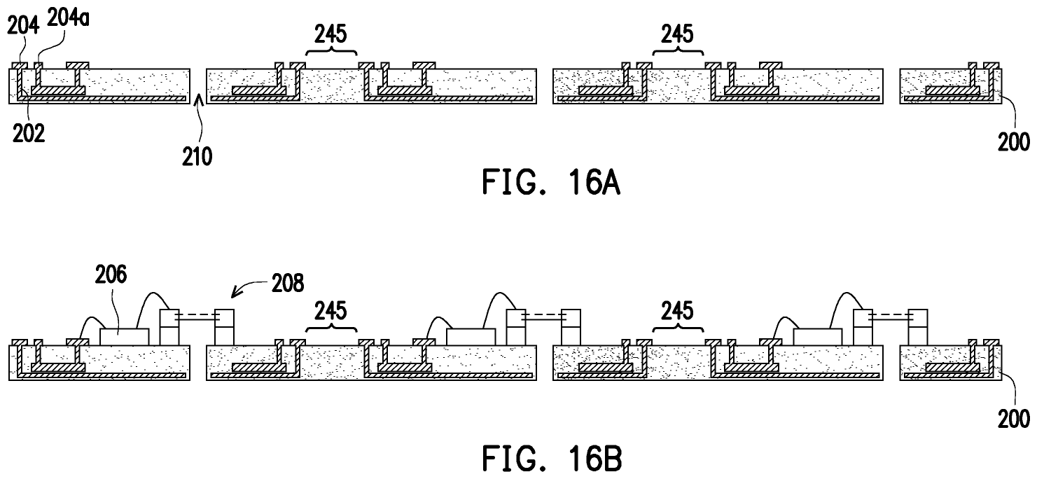

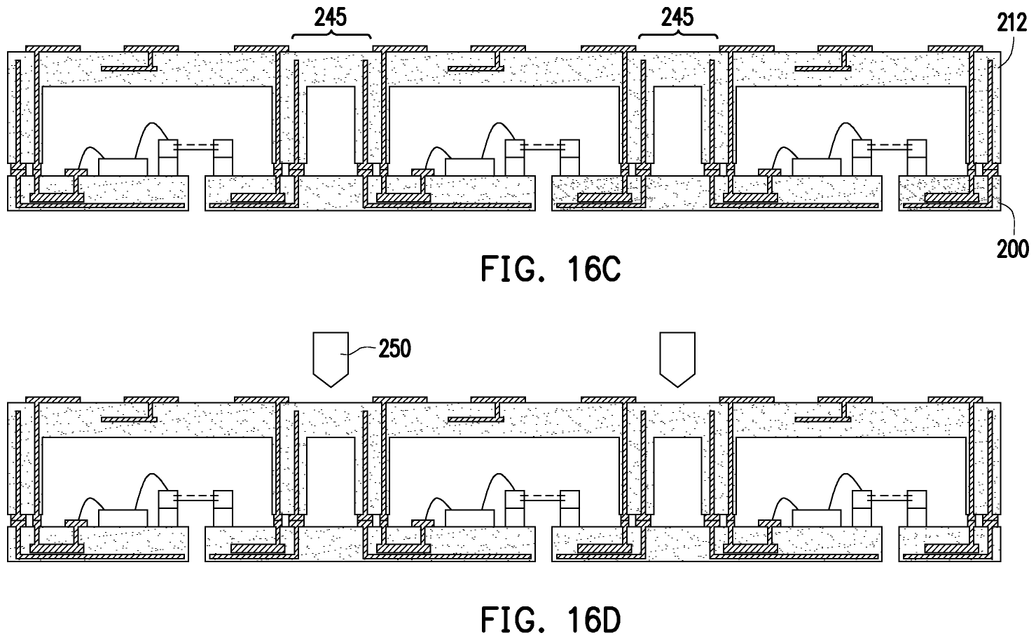

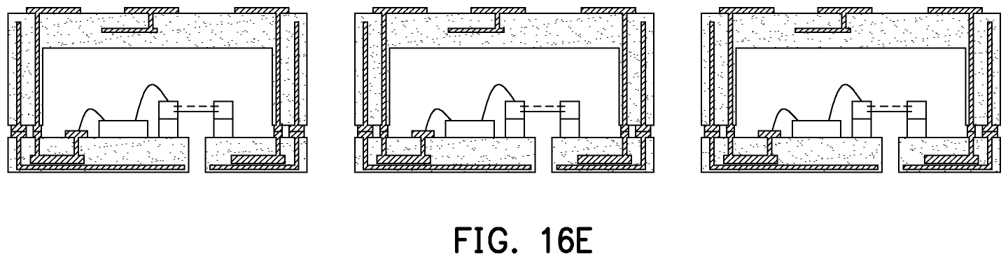

Further a packaging method for MEMS microphone is also described. FIG. 16A to FIG. 16E schematically illustrating a packaging process of MEMS microphone, according to an embodiment of the invention.

Referring to FIG. 16A, a ceramic packaging substrate 200 is provided. The ceramic packaging substrate 200 has been embedded with a circuit route 202. The circuit route 202 comprises a metal sealing ring 204 on a surface of the ceramic packaging substrate 200. In an embodiment, a circuit pad 204a may be also formed on the surface of the ceramic packaging substrate 200. The acoustic hole 210 may have also been formed already. The cutting region 245 is preserved in the ceramic packaging substrate 200 for cutting into dies at the end of packaging process.

Referring to FIG. 16B, the integrated circuit 206 and the MEMS microphone die 208 are disposed on a surface of the ceramic packaging substrate 200. The wire bonding is also performed to complete the circuit of the MEMS microphone as designed.

Referring to FIG. 16C, a cap structure 212 is provided and bonded onto the ceramic packaging substrate 200. The structure of the cap structure 212 has been described in foregoing embodiments, without further descriptions. However, each MEMS microphone is separated from the adjacent MEMS microphone by the cutting region 245. To bond the cap structure 212 and the ceramic packaging substrate 200, the eutectic technology or welding technology may be applied in an embodiment. The eutectic technology includes applying an ultrasonic vibration between the cap structure 212 and the ceramic packaging substrate 200 to produce heat due to friction. The metal mater is melted and joined after cooling in a rather short time. The welding technology may involve additional elements, which would be removed at the end of welding process. In other words for anther embodiment, the welding technology may be used in a seam welding process to join the metal maters and then bond the cap structure 212 and the ceramic packaging substrate 200 with also the sealing effect.

Referring to FIG. 16D, a cutting process 250 is performed at the cutting region 245. Referring to FIG. 16D, after the cutting process 250, each of MEMS microphones is in a single unit.

The invention discloses the way to package the MEMS microphone, in which the ceramic packaging substrate is used to adapt the integrated circuit and the MEMS microphone die. The ceramic packaging substrate provides the metal sealing ring, on which the cap structure is disposed on without involving the solder paste. The contamination of solder paste during the packaging process can be avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A package structure of micro-electro-mechanical-system (MEMS) microphone, comprising:
a ceramic packaging substrate, embedded with a first circuit route, wherein the first circuit route comprises a first metal sealing ring on a surface of the ceramic packaging substrate;
an integrated circuit, disposed on the surface of the ceramic packaging substrate;
a MEMS microphone die, disposed on the surface of the ceramic packaging substrate, wherein the MEMS microphone die is electrically connected to the integrated circuit; and
a cap structure, disposed on the first metal sealing ring of the ceramic packaging substrate, wherein the cap structure has a second metal sealing ring on a surface of the cap structure, wherein the second metal sealing ring is disposed on the first metal sealing ring, so that the cap structure covers on the ceramic packaging substrate.

2. The package structure of MEMS microphone as recited in claim 1,
wherein the first circuit route further comprises: a first metal circuit route embedded in the ceramic packaging substrate; and a first circuit pad on the surface of the ceramic packaging substrate,
wherein the cap structure is embedded with a second circuit route, the second circuit route comprises the second metal sealing ring and further comprises: a second metal circuit route embedded in the cap structure; and a second circuit pad on the surface of the cap structure,
wherein the second circuit pad is also disposed on the first circuit pad.

3. The package structure of MEMS microphone as recited in claim 1,
wherein the surface of the ceramic packaging substrate is a flat surface to accept the MEMS microphone die and the integrated circuit,
wherein the surface of the cap structure has a depression portion corresponding to the MEMS microphone die and the integrated circuit.

4. The package structure of MEMS microphone as recited in claim 1,
wherein the surface of the ceramic packaging substrate has a depression portion to accept the MEMS microphone die and the integrated circuit,
wherein the surface of the cap structure is a flat surface.

5. The package structure of MEMS microphone as recited in claim 1,
wherein the surface of the ceramic packaging substrate has a first depression portion to accept the MEMS microphone die and the integrated circuit,
wherein the surface of the cap structure has a second depression portion corresponding to the MEMS microphone die and the integrated circuit.

6. The structure of MEMS microphone package as recited in claim 1,
wherein the surface of the ceramic packaging substrate has a first depression portion to accept the MEMS microphone die and the integrated circuit and the ceramic packaging substrate further has an indent under the MEMS microphone die or under both the MEMS microphone die and the integrated circuit,
wherein the surface of the cap structure has a second depression portion corresponding to the MEMS microphone die and the integrated circuit.

7. The package structure of MEMS microphone as recited in claim 1, wherein the surface of the ceramic packaging substrate is a flat surface or has a depression portion to accept the MEMS microphone die and the integrated circuit.

8. The package structure of MEMS microphone as recited in claim 1, wherein the surface of the cap structure is a flat surface or has a depression portion.

9. The package structure of MEMS microphone as recited in claim 1, wherein one of the ceramic packaging substrate and the cap structure has an acoustic hole.

10. The package structure of MEMS microphone as recited in claim 1, wherein the cap structure is ceramic and comprises a shielding metal layer as embedded and connected to the second metal sealing ring.

11. The package structure of MEMS microphone as recited in claim 1, wherein the ceramic packaging substrate comprises a vertical metal wall as embedded and connected to the first metal sealing ring.

12. The package structure of MEMS microphone as recited in claim 1, wherein the cap structure is ceramic and comprises a shielding metal wall as embedded and connected to the second metal sealing ring.

13. A package structure of micro-electro-mechanical-system (MEMS) microphone, comprising:
a ceramic packaging substrate, embedded with a circuit route, wherein the circuit route comprises a metal sealing ring on a surface of the ceramic packaging substrate, the circuit route also comprises a circuit pad on the surface of the ceramic packaging substrate;
an integrated circuit, disposed on the surface of the ceramic packaging substrate and connected to circuit pad of the circuit route;
a MEMS microphone die, disposed on the surface of the ceramic packaging substrate, wherein the MEMS microphone die is electrically connected to the integrated circuit; and
a metal cap structure, disposed on the first metal sealing ring.

14. A packaging method for micro-electro-mechanical-system (MEMS) microphone, comprising:
providing a ceramic packaging substrate, embedded with a first circuit route, wherein the first circuit route comprises a first metal sealing ring on a surface of the ceramic packaging substrate;
disposing an integrated circuit on the surface of the ceramic packaging substrate;
disposing a MEMS microphone die on the surface of the ceramic packaging substrate, wherein the MEMS microphone is electrically connected to the integrated circuit;
providing a cap structure, having a second metal sealing ring on a surface of the cap structure; and
applying a bonding process to at least bond the second metal sealing ring and the first metal sealing ring, so that the cap structure covers on the ceramic packaging substrate.

15. The packaging method for MEMS microphone as recited in claim 14, wherein the bonding process comprises applying an ultrasonic vibration or a seam welding process on an interface between the second metal sealing ring and the first metal sealing ring to melt a metal interface and then solidifying the metal interface.

16. The packaging method for MEMS microphone as recited in claim 14, wherein the surface of the ceramic packaging substrate is a flat surface or has a depression portion to accept the MEMS microphone die and the integrated circuit.

17. The packaging method for MEMS microphone as recited in claim 14, wherein the surface of the cap structure is a flat surface or has a depression portion.

18. The packaging method for MEMS microphone as recited in claim 14,
wherein the first circuit route further comprises: a first circuit route embedded in the ceramic packaging substrate; and a first circuit pad on the surface of the ceramic packaging substrate,
wherein the cap structure is a ceramic cap embedded with a second circuit route, the second circuit route comprises the second metal sealing ring and further comprises: a second circuit route embedded in the cap structure; and a second circuit pad on the surface of the cap structure,
wherein the second circuit pad is also disposed on the first circuit pad.

19. The packaging method for MEMS microphone as recited in claim 14,
wherein the first circuit route further comprises: a first circuit route embedded in the ceramic packaging substrate; and a first circuit pad on the surface of the ceramic packaging substrate,
wherein the cap structure is metal cap.

20. The packaging method for MEMS microphone as recited in claim 14,
wherein the surface of the ceramic packaging substrate is a flat surface to accept the MEMS microphone die and the integrated circuit,
wherein the surface of the cap structure has a depression portion corresponding to the MEMS microphone die and the integrated circuit.
